(19) United States
(12) Patent Application Publication
(10) Pub. No.: US 2006/0030120 A1
(43) Pub. Date: Feb. 9, 2006

(54) METHOD OF PERFORMING DOUBLE-SIDED PROCESSES UPON A WAFER

(76) Inventors: Shih-Feng Shao, Taipei Hsien (TW); Chih-Ping Kuo, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 10/904,741

(22) Filed: Nov. 24, 2004

(30) Foreign Application Priority Data
Aug. 6, 2004 (TW) 093123586

(51) Int. Cl. H01L 21/30

(52) U.S. Cl. 438/455

(57) ABSTRACT

First, a wafer having a first surface and a second surface is provided. Then, a first heat sensitive tape is utilized to bond the second surface of the wafer to a first carrier, and at least a first semiconductor process is performed upon the first surface of the wafer. Subsequently, a second heat sensitive tape is utilized to bond the first surface of the wafer to a second carrier, and the first heat sensitive tape is separated from the second surface of the wafer by heating. Following that, at least a second semiconductor process is performed upon the second surface of the wafer, and the second heat sensitive tape is separated from the first surface of the wafer by heating.

### BACKGROUND OF INVENTION

1. Field of the Invention

The present invention pertains to a method of performing double-sided processes upon a wafer, and more particularly, to a method of performing double-sided processes by means of two heat sensitive tapes having different separating temperatures.

2. Description of the Prior Art

With the rapid development of semiconductor technology and improvement of semiconductor element integration, semiconductor processes have already been applied to fabricate various MEMS devices, such as micro sensors, micro actuators, etc. MEMS devices have more complicated mechanical structures than semiconductor devices, e.g. through-hole structures or micro spindle structures, and thus must be fabricated by double-sided processes. However, double-sided processes are not standard semiconductor processes, and thus cannot be implemented by current semiconductor apparatuses. Specifically, the wafer for fabricating MEMS devices is thinner than a semiconductor wafer, and thus is more fragile. Without appropriate fastening mechanism and protection, the MEMS wafer is easily broken or cracked during process or transportation.

Please refer to FIG. 1 and FIG. 2. FIG. 1 and FIG. 2 are schematic diagrams illustrating a conventional method of performing double-sided processes. As shown in FIG. 1, a wafer 10 including a front surface 12 and a back surface 14 is provided. The front surface 12 and the back surface 14 of the wafer 10 are respectively needed to be treated with at least a semiconductor process, such as a lithography process, an etching process, or a polishing process, so as to form a desired structure. When a front side process is performed upon the front surface 12, the back surface 14 is fastened with a vacuum chuck 16 frequently utilized in the semiconductor processes to ensure precise alignment of the wafer 10. As shown in FIG. 2, the wafer 10 is turned over after the front side pattern 12A is completed. Following that, a back side process is performed upon the back surface 14 of the wafer 10 to form the back side pattern 14A. However, when performing the back side pattern 14A, the front surface 12 having the front side pattern 12A thereon is fastened with the vacuum chuck 16. In such a case, the front side pattern 12A tends to be damaged due to friction or impact. In addition, if the wafer 10 is desired to form devices having through hole structures, the attraction effect of the vacuum chuck 16 on the front surface 12 will degrade or even fail. This leads to misalignment of the back side pattern 14A, or even causes the wafer 10 to depart from the vacuum chuck 16.

In addition to the aforementioned method of performing double-sided processes, another conventional method of double-sided processes is frequently applied to back-end package double-sided processes. Please refer to FIG. 3 through FIG. 7. FIG. 3 through FIG. 7 are schematic diagrams illustrating another conventional method of performing back-end package double-sided processes. As shown in FIG. 3, a wafer 30, having a front surface 32 and a back surface 34, is provided. Then, an UV tape 36 is bonded to the back surface 34, thereby fastening the wafer 30 to a metal frame 38. As shown in FIG. 4, a cutter 40 of a segment apparatus (not shown) is used to perform a front side segment process in which the wafer 30 is cut to a desired extent, but not completely cut off.

As shown in FIG. 5, the wafer 30 is subsequently turned over and another UV tape 42 is used to fasten the front surface 32 to a glass wafer 44. Following that, the UV tape (not shown) adhered to the back surface 32 is irradiated by UV beams so as to separate the wafer 30 from the metal frame 38. Then, as shown in FIG. 6, a polish apparatus 46 is used to carry out a polishing process upon the back surface 34, and therefore a plurality of dies 48 are formed. As shown in FIG. 7, the UV tape 42 is then irradiated by UV beams from the back side of the glass wafer 44 so as to separate the dies 48 from the glass wafer 44.

The above method is capable of fastening the wafer 30, but is limited to back-end package double-sided processes. This is because UV tape is not resistant to high temperature and organic solvents. If this method is applied to front-end double-sided processes in which process temperature is higher and organic solvents are frequently required (e.g. in an etching process), the UV tape 36 and 42 will degrade and fail to fasten the wafer 30.

In the prior art, there is another method in which the UV tape is replaced with a photoresist layer (or a wax layer). However, the photoresist layer is bonded to the front surface of the wafer and a carrier when performing back side processes, and therefore the organic solvent used to strip off the photoresist layer can only reach the photoresist layer laterally. It thus takes hours to remove the photoresist layer, which is very ineffective.

Due to the above disadvantages or limitations, an improved method able to be applied to both the front-end and back-end double-sided processes is required to improve yield.

### SUMMARY OF INVENTION

It is therefore a primary object of the claimed invention to provide an improved method of performing double-sided processes to overcome the aforementioned problems.

According to the claimed invention, a method of performing double-sided processes is disclosed. First, a wafer having a first surface and a second surface is provided. Then, a first heat sensitive tape is utilized to bond the second surface of the wafer to a first carrier, and at least a first semiconductor process is performed upon the first surface of the wafer. Subsequently, a second heat sensitive tape is utilized to bond the first surface of the wafer to a second carrier, and the first heat sensitive tape is separated from the second surface of the wafer by heating. Following that, at least a second semiconductor process is performed upon the second surface of the wafer, and the second heat sensitive tape is separated from the first surface of the wafer by heating.

The present invention makes use of a first heat sensitive tape and a second heat sensitive tape to respectively the front surface and the back surface of a wafer, and thus the wafer is stably fastened when performing the front side process and the back side process. In addition, the first heat sensitive tape and the second heat sensitive tape have different separating temperatures, and one of them can be easily removed without affecting the bonding ability of the other. Consequently, structures formed on the wafer will not be damaged and the yield is therefore improved.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 and FIG. 2 are schematic diagrams illustrating a conventional method of performing double-sided processes.

FIG. 3 through FIG. 7 are schematic diagrams illustrating another conventional method of performing back-end package double-sided processes.

FIG. 8 through FIG. 12 are schematic diagrams illustrating a method of performing double-sided processes according to a preferred embodiment of the present invention.

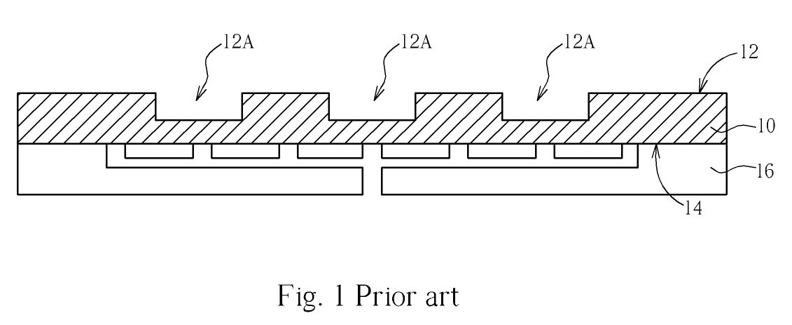

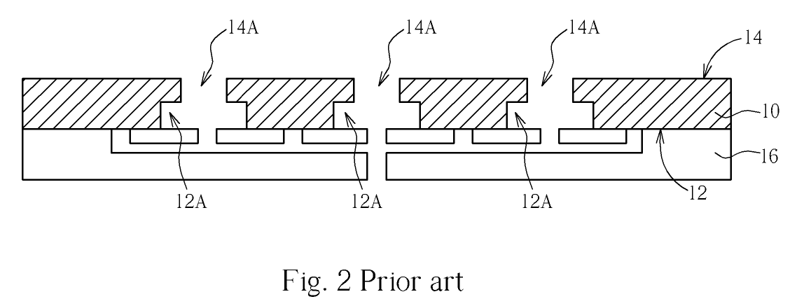

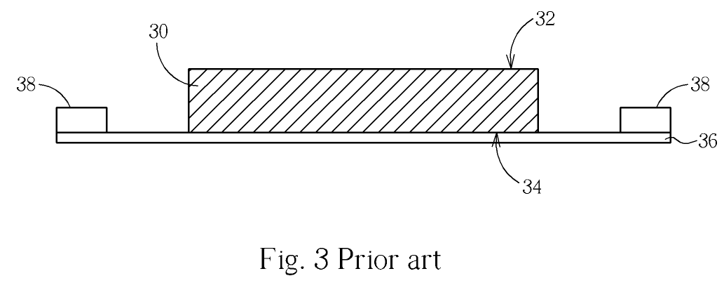

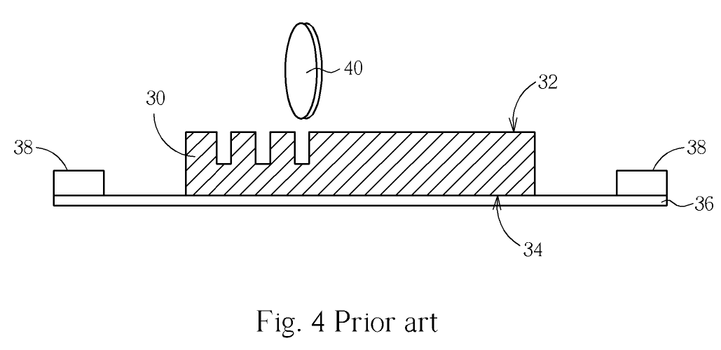

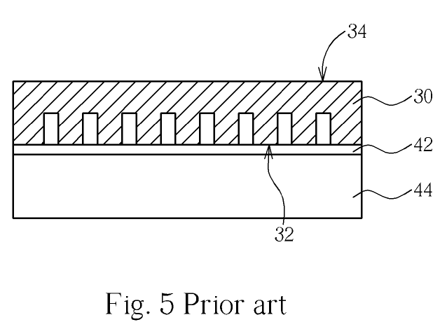

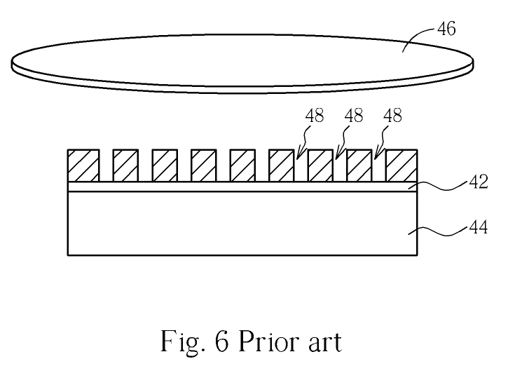

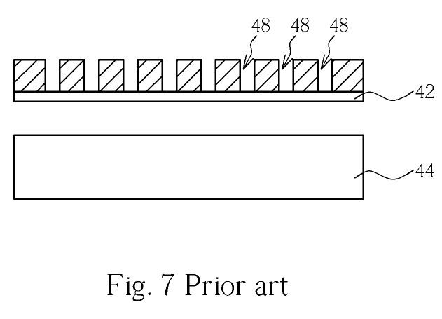

### DETAILED DESCRIPTION

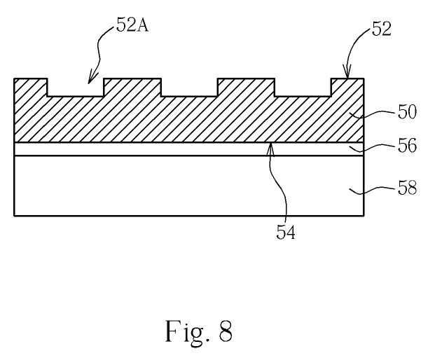

Please refer to FIG. 8 through FIG. 12. FIG. 8 through FIG. 12 are schematic diagrams illustrating a method of performing double-sided processes according to a preferred embodiment of the present invention. As shown in FIG. 8, a wafer 50, having a front surface 52 and a back surface 54, is provided. Then, a first heat sensitive tape 56 is utilized to bond the back surface 54 to a first carrier 58. Subsequently, at least a semiconductor process, such as a lithography process, an etching process, or a polishing process, is performed upon the front surface 52 to form a front side pattern 52A on the front surface 52.

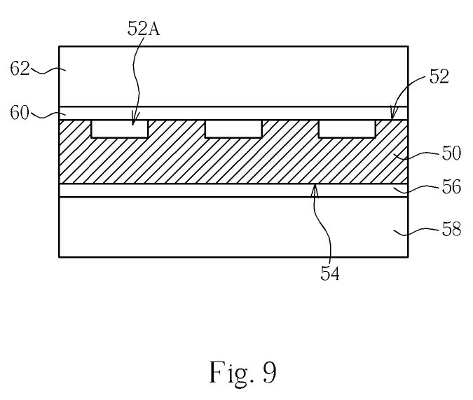

As shown in FIG. 9, a second heat sensitive tape 60 is utilized to bond the front surface 52 to a second carrier 62 when the front side pattern 52A is formed. The first carrier 58 and the second carrier 62 both have a size similar to that of the wafer 50, so as to support the wafer 50 and ensure a good alignment effect. In addition, the material of the first carrier 58 and the second carrier 62 is selected from glass, quartz, silicon, ceramics, or other suitable materials inert to the process reactants at high temperature during the semiconductor process.

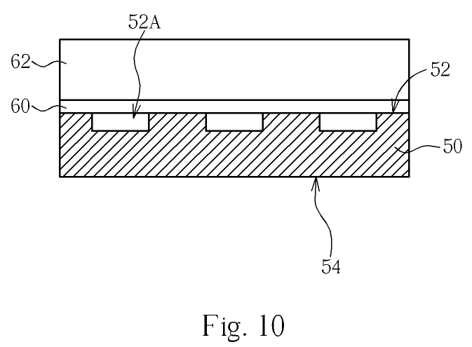

As shown in FIG. 10, after the front surface 52 of the wafer 50 is tightly fastened to the second carrier 62 with the second heat sensitive tape 60, the wafer 50 is heated so that the bonding ability of the first heat sensitive tape 56 is diminished. Consequently, the wafer 50 is separated from the first carrier 58. It is appreciated that heat sensitive tape is adhesive on both sides, and compatible with semiconductor processes. The bonding ability of heat sensitive tape is good under its separating temperature but degrades as temperature rises over its separating temperature, thus the present invention takes advantage of this characteristic. In this embodiment, when performing the front side process, the back surface 54 of the wafer 50 is adhered to the first carrier 58 with the first heat sensitive tape 56, and the front surface 52 of the wafer 50 is then adhered to the second carrier 62 with the second heat sensitive tape 60 after the front side pattern 52A is formed. Following that, the wafer 50 is heated to separate the back surface 54 from the first carrier 58, and the back side process is then performed upon the back surface 54 of the wafer 50. Since the separating temperature of the first heat sensitive tape 56 is lower than that of the second heat sensitive tape 60, the first heat sensitive tape 56 loses its bonding ability when the temperature is higher than its separating temperature while the second heat sensitive tape 62 remains adhesive. Thus, the front surface 52 of the wafer 50 is still tightly bonded to the second carrier 62, and allows the back surface 54 to undergo the back side process.

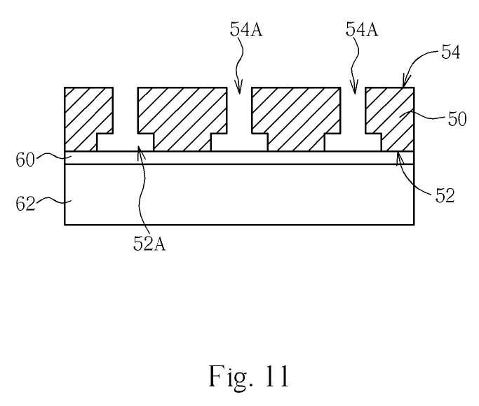

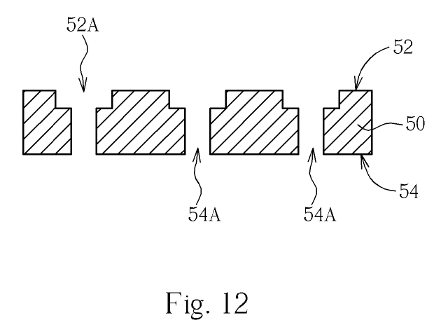

As shown in FIG. 11, at least a semiconductor process is performed upon the back surface 54 of the wafer 50 to form the back side pattern 54A. Accordingly, the front side pattern 52A and the back side pattern 54A are completed. Finally as shown in FIG. 12, the wafer 50 is heated again to a temperature higher than the separating temperature of the second heat sensitive tape 60 for separating the wafer 50 from the second carrier 62.

It is to be appreciated that the present invention is not limited to the above embodiment in which two heat sensitive tapes having different separating temperatures are utilized. Other bonding layer can be utilized in combination with the heat sensitive tape. For example, when the back surface 54 of the wafer 50 is bonded to the first carrier 58 with the first heat sensitive tape 56, other bonding layers, such as an UV tape, a blue tape, wax, or photo resist, which can be separated in another manner, specifically, in a non-heating way, can be utilized in place of the second heat sensitive tape 60. Similarly, the bonding layer can also be utilized in place of the first heat sensitive tape 56. In such cases, the bonding layer or the heat sensitive tape can be deprived of its bonding ability without influencing the adhesion of the other. It is to be noted that material characteristics of the bonding layer must be taken into consideration so as to ensure the bonding ability during different semiconductor processes.

In the above embodiment, the present invention is applied to front-end double-sided processes, such as etching processes or lithography processes, However, the present invention can also be applied to back-end double-sided processes, such as package processes, to simplify process complexity.

In comparison with the prior art, the present invention utilizes two bonding layers having different separation conditions, and thus the wafer is safely fastened when performing front side processes and back side processes. In addition, for an MEMS wafer, which is thinner (frequently thinner than 300 μm) and often has through hole structures thereon, the present invention is able to provide desirable bonding and alignment effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of performing double-sided processes upon a wafer, comprising:
providing a wafer comprising a first surface and a second surface;
utilizing a first heat sensitive tape to bond the second surface of the wafer to a first carrier, and performing at least a first semiconductor process upon the first surface of the wafer;
utilizing a second heat sensitive tape to bond the first surface of the wafer to a second carrier, and separating the first heat sensitive tape from the second surface of the wafer by heating;
performing at least a second semiconductor process upon the second surface of the wafer; and
separating the second heat sensitive tape from the first surface of the wafer by heating.

2. The method of claim 1, wherein a separating temperature of the first heat sensitive tape is less than that of the second heat sensitive tape.

3. The method of claim 1, wherein the first semiconductor process is performed at a process temperature less than a separating temperature of the first heat sensitive tape.

4. The method of claim 1, wherein the second semiconductor process is performed at a process temperature less than a separating temperature of the second heat sensitive tape.

5. A method of performing double-sided processes upon a wafer, comprising:
providing a wafer comprising a first surface and a second surface;
utilizing a first bonding layer to bond the second surface of the wafer to a first carrier, and performing at least a first semiconductor process upon the first surface of the wafer;
utilizing a second bonding layer to bond the first surface of the wafer to a second carrier, and separating the first bonding layer from the second surface of the wafer;
performing at least a second semiconductor process upon the second surface of the wafer; and
separating the second bonding layer from the first surface of the wafer; wherein the first bonding layer and the second bonding layer are separated in different manners.

6. The method of claim 5, wherein a separating temperature of the first bonding layer is less than that of the second bonding layer.

7. The method of claim 5, wherein the first bonding layer is separated by heating, and the second bonding layer is separated in a non-heating manner.

8. The method of claim 5, wherein the second bonding layer is separated by heating, and the first bonding layer is separated in a non-heating manner.

9. The method of claim 5, wherein the first bonding layer is a heat sensitive tape.

10. The method of claim 9, wherein the second bonding layer is selected from the group consisting of photoresist, UV tape, wax, and blue tape.

11. The method of claim 5, wherein the second bonding layer is a heat sensitive tape.

12. The method of claim 11, wherein the first bonding layer is selected from the group consisting of photoresist, UV tape, wax, and blue tape.
